(19) United States
(12) Patent Application Publication
(10) Pub. No.: US 2006/0273866 A1
(43) Pub. Date: Dec. 7, 2006

(54) Film bulk acoustic wave resonator with differential topology

(75) Inventor: Ari Vilander, Kerava (FI)

Correspondence Address: SQUIRE, SANDERS & DEMPSEY L.L.P., 14TH FLOOR, 8000 TOWERS CRESCENT, TYSONS CORNER, VA, 22182, US

(73) Assignee: Nokia Corporation

(21) Appl. No.: 11/146,118

(22) Filed: Jun. 7, 2005

(51) Int. Cl. H03H 9/56

(52) U.S. Cl. 333/187; 333/191

(57) ABSTRACT

The present invention relates to a resonator structure, such as a film bulk acoustic wave (FBAW) resonator structure, which is modified to approximate a parasitic input characteristic to a parasitic output characteristic and thus enable use of the resonator structure in a differential topology. Thereby, crystal-based resonator structures can be replaced by the proposed differential resonator structure, which enables higher integration, reduced costs and higher frequencies. A crystal based oscillator cannot handle frequencies above 40 MHz in fundamental mode.

### FIELD OF THE INVENTION

The present invention relates to a resonator structure integrated on a substrate. In particular the present invention relates to a film bulk acoustic wave resonator (FBAR) structure.

### BACKGROUND OF THE INVENTION

The development of mobile telecommunications continues towards ever smaller and increasingly complicated handheld units or mobile phones. The development has recently lead to new requirements for handheld units, namely that the units should support several different standards and telecommunications systems. Supporting several different systems requires several sets of filters and other radio frequency (RF) components in the RF parts of the handheld units. Despite this complexity, the size of a handheld unit should not increase as a result of such a wide support.

RF filters used in prior art mobile phones are usually discrete surface acoustic wave (SAW) or ceramic filters. This approach has been adequate for single standard phones, but does not allow support of several telecommunications systems without increasing the size of a mobile phone.

Surface acoustic wave (SAW) resonators utilize surface acoustic vibration modes of a solid surface, in which modes the vibration is confined to the surface of the solid, decaying quickly away from the surface. A SAW resonator typically comprises a piezoelectric layer and two electrodes. Various resonator structures such as filters are produced with SAW resonators. A SAW resonator has the advantage of having a very small size, but unfortunately cannot withstand high power levels.

It is known to construct thin film bulk acoustic wave (BAW) resonators on semiconductor wafers, such as silicon (Si) or gallium arsenide (GaAs) wafers. For example, in an article entitled “Acoustic Bulk Wave Composite Resonators”, Applied Physics Letters, Vol. 38, No. 3, pp. 125-127, Feb. 1, 1981,by K. M. Lakin and J. S. Wang, an acoustic bulk wave resonator is disclosed which comprises a thin film piezoelectric layers of zinc oxide (ZnO) sputtered over a thin membrane of silicon (Si). Further, in an article entitled “An Air-Gap Type Piezoelectric Composite Thin Film Resonator”, 15 Proc. 39th Annual Symp. Freq. Control, pp. 361-366, 1985, by Hiroaki Satoh, Yasuo Ebata, Hitoshi Suzuki, and Choji Narahara, a BAW resonator having a bridge structure is disclosed. Examples of BAW resonator circuits are also disclosed in EP-A-0962999 and EP-A-0834989.

BAW resonators are not yet in widespread use, partly due to the reason that feasible ways of combining such resonators with other circuitry have not been presented. However, BAW resonators have some advantages as compared to SAW resonators. For example, BAW structures have a better tolerance of high power levels.

FIG. 1 shows a cross section of a conventional FBAR isolated from a substrate 30 (e.g. an Si-substrate) by an acoustic mirror structure 18. The FBAR comprises a bottom electrode BE, a piezoelectric layer or film 160, and a top electrode TE. The acoustical mirror structure 18 comprises in this example three layers. Two of the layers are formed of a first material, and the third layer in between the two layers is formed from a second material. The first and second materials have different acoustical impedances. The order of the materials can be different in different examples. In some examples, a material with a high acoustical impedance can be in the middle and a material with a low acoustical impedance on both sides of the middle material. In other examples., the order can be opposite. The bottom electrode BE may in some embodiments function as one layer of the acoustical mirror.

In FIG. 1, the active part 16 of the FBAR is indicated by the dashed rectangle. The electronic characteristic between the bottom electrode BE and the substrate 30 can be represented by a bottom electrode parasitic circuit BEP which comprises a series connection of parasitic capacitors CoxM1 to CoxM3 at the acoustical mirror structure 18, followed by a parallel circuit of a substrate resistor RsuM and a substrate capacitor CsuM. Furthermore, resistors Rsb and Rst represent ohmic resistances of the respective conductor paths between the bottom electrode BE and a bottom electrode terminal 24 and between the top electrode TE and a top electrode terminal 22. The electronic characteristic between the top electrode TE and the substrate 30 can be represented by a top electrode parasitic circuit TEP which comprises a series connection of a parasitic capacitor CoxT and a parallel circuit of a substrate resistor RsuT and a substrate capacitor CsuT. Moreover, a parasitic capacitance Ctb is provided between the top electrode TE and the bottom electrode BE. Thus, the electrodes of the conventional FBAR are slightly different because the bottom electrode BE has more parasitic capacitance than the top electrode TE.

FIG. 2 shows a schematic circuit model of the conventional FBAR, as obtained on the basis of parasitic circuits BEP and TEP, the parasitic capacitance Ctb and the resistors Rsb and Rst. In FIG. 2, Rs designates a series resistance of the FBAR, Cox designates the capacitance between the bottom electrode BE and the substrate 30, Rsu and Csu designate elements of a circuit model of the substrate losses, and Ra, La, Ca and CO designate elements of a circuit model of the active part 16.

Due to high center frequencies of FBARs, e.g. 500 MHz and higher, oscillator circuits employing FBARs should be operated in a differential topology to keep sensitivity to external disturbances and noise small. However, as indicated in FIG. 2, the ports or terminals of the FBAR have different parasitic circuitries and thus the FBAR will not work properly in a differential topology.

### SUMMARY OF THE INVENTION

It is therefore an object of the present invention to provide an improved resonator structure which can be employed in a differential topology.

According to a first aspect of the present invention, this object is achieved by a resonator structure integrated on a substrate and comprising:
an acoustically active layer;
first and second electrodes arranged on opposite sides of said acoustically active layer; and
isolation means for acoustically isolating said acoustically active layer from said substrate;
wherein said first electrode is extended by a predetermined amount beyond said acoustically active layer, so as to approximate a parasitic input characteristic to a parasitic output characteristic of said resonator structure.

Furthermore, according to a second aspect of the present invention, the above object is achieved by a resonator structure integrated on a substrate and comprising:
a first resonator structure having a first acoustically active layer; first opposite electrodes arranged on opposite sides of said first acoustically active layer, and first isolation means for acoustically isolating said first acoustically active layer from said substrate;
a second resonator structure having a second acoustically active layer; second opposite electrodes arranged on opposite sides of said second acoustically active layer, and second isolation means for acoustically isolating said second acoustically active layer from said substrate;
wherein said first and second opposite electrodes of said first and second resonator structures are connected in an anti-parallel or anti-serial manner, so as to approximate a parasitic input characteristic to a parasitic output characteristic of said resonator structure.

Accordingly, the parasitic input and output characteristics of the proposed resonator structures are approximated to each other in both aspects, to thereby enable use in a differential topology. Conventional crystal-based resonator structures can thus be replaced, e.g., in oscillator circuits. This enables higher integration levels and reduced manufacturing costs. Moreover, the differential topology is less sensitive to external noise and other disturbances.

The first electrode may be arranged on top of a layered structure comprising the acoustically active layer, the second electrode, the isolation means and the substrate.

In the first aspect, the isolation means may be extended substantially in parallel to the first electrode and substantially by the same amount. As an example, the first electrode may be extended by an amount which substantially corresponds to the length of the second electrode in the direction of extension.

The isolation means may for example comprise a layered acoustic mirror structure.

In the second aspect, a top electrode of the first opposite electrodes may be arranged as a top layer of a layered structure forming the first resonator structure and the substrate, and a top electrode of the second opposite electrodes is arranged as top layer of a layered structure forming the second resonator structure and the substrate, and wherein the anti-parallel structure is obtained by connecting the top electrode of the first opposite electrodes to a bottom electrode of the second opposite electrodes and by connecting the top electrode of the second opposite electrodes to a bottom electrode of the first opposite electrodes.

As an alternative, the top electrode of the first opposite electrodes may be arranged as a top layer of a layered structure forming the first resonator structure and the substrate, and a top electrode of the second opposite electrodes is arranged as a top layer of a layered structure forming the second resonator structure and the substrate, and wherein the anti-serial structure is obtained by connecting a bottom electrode of the first opposite electrodes to a bottom electrode of the second opposite electrodes.

The proposed resonator structures according to the first and second aspects may be provided in differential topology in an oscillator circuit which may be provided in a terminal device, such as a mobile phone or other wireless device. According to a first example, the resonator structure may be arranged in a diagonal path of a bridge configuration of differentially operated transistor elements. According to a second example, the resonator structure may be connected between source electrodes of differentially operated transistor elements.

Further advantageous modifications are defined in the dependent claims.

### BRIEF DESCRIPTION OF THE DRAWINGS

The present invention will now be described based on preferred embodiments with reference to the accompanying drawings in which:

FIG. 1 shows a schematic cross section of a conventional resonator structure;

FIG. 2 shows a schematic circuit model of the conventional resonator structure of FIG. 1;

FIG. 3 shows a schematic cross section of a resonator structure according to a first preferred embodiment;

FIG. 4 shows a schematic circuit model of the resonator structure of FIG. 3;

FIG. 5 shows a resonator structure comprising two anti-parallel resonators, according to a second preferred embodiment;

FIG. 6 shows a resonator structure comprising two anti-serial resonators, according to a third preferred embodiment;

FIG. 7 shows a schematic diagram indicating a phase behavior of a resonator structure according to the preferred embodiments;

FIG. 8 shows a schematic circuit diagram of a first example of a resonator structure according to the preferred embodiments;

FIG. 9 shows a schematic circuit diagram of a second example of a resonator structure according to the preferred embodiments; and

FIG. 10 shows a schematic block diagram of a mobile communication device in which the present invention can be employed.

### DESCRIPTION OF THE PREFERRED EMBODIMENT

In the following, the preferred embodiments will be described in connection with a FBAR structure for use in an oscillator circuit with differential topology which it is more robust and not as sensitive as a single-end topology where one port or terminal of the resonator structure is connected to a fixed potential. In particular, the preferred embodiments are focused on a use of FBAR as an oscillator tank circuit. This kind of oscillator is common useful for reference purpose, when phase noise requirements are very tight. Thereby, conventional crystal-based oscillators can be replaced by FBAW-based oscillators.

According to the preferred embodiments, differential use of the proposed FBAR structure is achieved by approximating or equalizing the parasitic characteristics at both ports of the FBAR structure. This can be achieved by changing the internal structure of a single resonator or by connecting several resonators in a manner to provide substantially the same overall parasitic characteristic at both ports of the resonator structure.

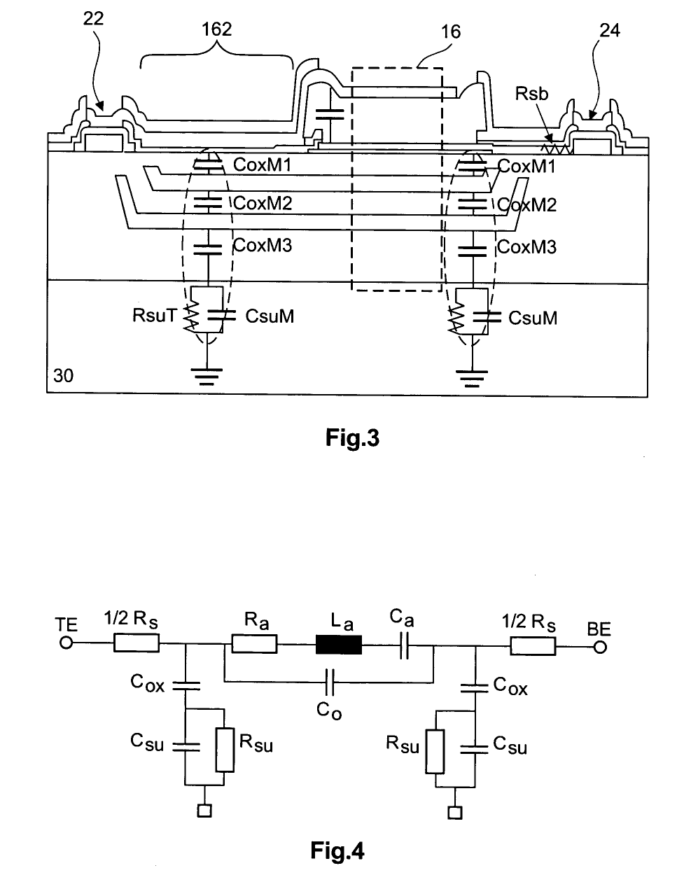

FIG. 3 shows a schematic cross section of a FBAR structure according to the first preferred embodiment. The parasitic characteristic between the top electrode and the substrate 30 is modified and approximated to the parasitic characteristic between the bottom electrode and the substrate 30 by providing a stretched or extended top electrode portion 162 obtained by stretching or extending the top electrode and the acoustic mirror structure by a predetermined amount. In the first preferred embodiment, the predetermined amount stretched corresponds to the width or length of the bottom electrode in the direction of extension. Thereby, the parasitic circuits at the top and bottom electrodes are substantially made equal or approximated to each other, so as to obtain a differential structure. This kind of resonator can thus be used directly for differential oscillator purposes.

It is noted that any modification of the top electrode structure suitable to approximate or equalize the parasitic circuits at both electrodes are intended to be covered by the present invention. As an alternative, the acoustic mirror structure 18 not necessarily has to be extended as well, provided that the parasitic capacitance at the top electrode is suitably adapted by introducing other modifications of the integrated structure in order to obtain the same parasitic characteristic as at the bottom electrode.

FIG. 4 shows a schematic circuit model of the stretched FBAR structure of FIG. 3, as obtained on the basis of the modified top electrode structure. Now, the circuit model is symmetrical and both top and bottom electrodes TE, BE have equal parasitic circuits and characteristics due to their similar integration structures. The stretched FBAR structure is thus useful for differential circuits, such as oscillator circuits.

In the following, an alternative approach for obtaining a symmetrical resonator structure is described in connection with the second and third preferred embodiment. Here, two FBAR structures are combined to obtained a symmetrical overall resonator structure structured as a differential tank circuit, which can be used in differential circuit environments.

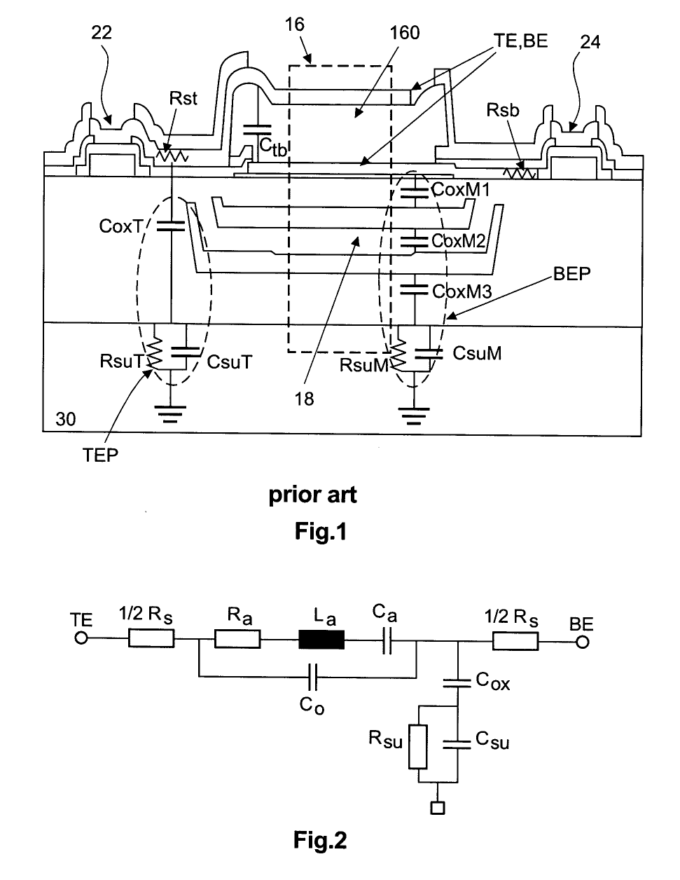

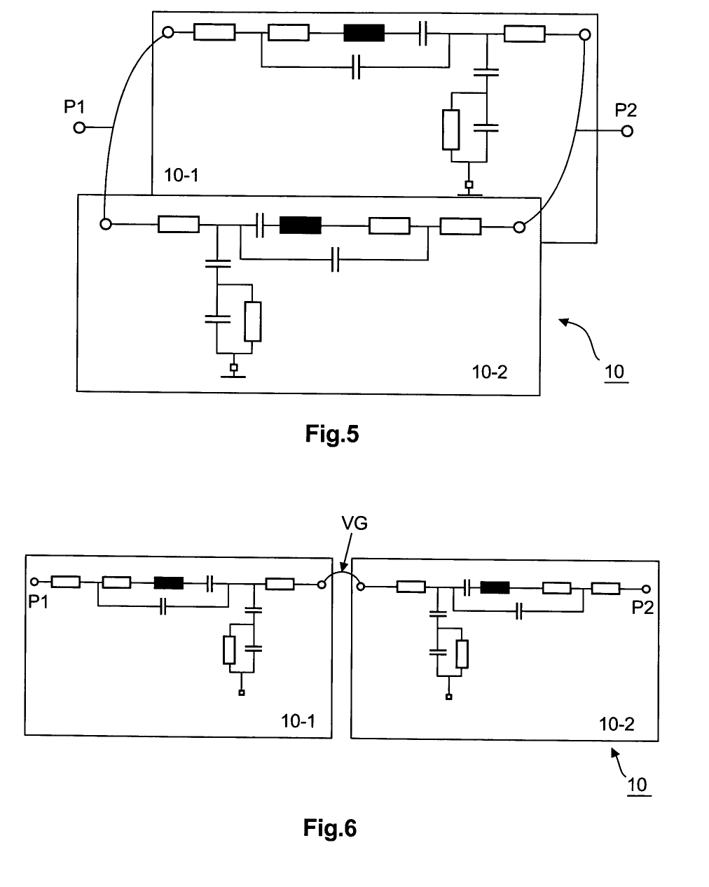

FIG. 5 shows a schematic circuit model of a combined FBAR structure 10 according to the second preferred embodiment, where two FBARs (structured e.g. as shown in FIG. 1) are connected to each other in an anti-parallel manner. That is, the bottom electrode of a first FBAR 10-1 is connected to the top electrode of a second FBAR 10-2 and vice versa. The first and second FBARs may be integrated on the same substrate, wherein two ports P1, P2 of the FBAR structure 10 are provided at a connection point of the respective top and bottom electrodes.

FIG. 6 shows a schematic circuit model of a combined FBAR structure 10 according to the third preferred embodiment, where two FBARs (structured e.g. as shown in FIG. 1) are connected to each other in an anti-serial manner. That is, the bottom electrodes of a first FBAR 10-1 is connected to the bottom electrode of a second FBAR 10-2 and ports P1, P2 are provided at the respective top electrodes. Again, the first and second FBARs may be integrated on the same substrate, so that deviation of center frequency is as small as possible (approx. 50 kHz). The serial third embodiment provides the additional advantage that a virtual ground VG is automatically obtained at the connection point between the first and second resonators 10-1, 10-2. The virtual ground VG makes it possible to drive a DC voltage over the combined resonator structure 10 in a simple way.

As can be gathered from FIG. 5 and 6, the connection of the two circuit models of the first and second FBARs 10-1 and 10-2 leads to overall circuit models which are symmetric with respect to their ports P1 and P2.

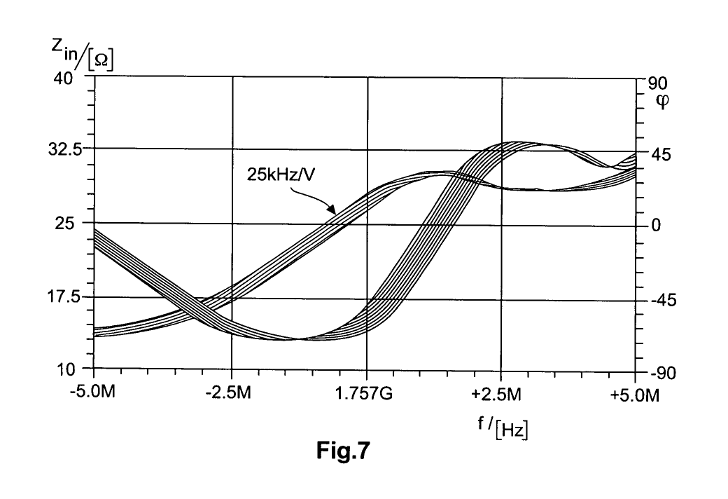

FIG. 7 shows a schematic diagram of the phase behavior of a FBAR structure versus an applied DC voltage. The FBAR has natural sensitivity for DC voltage applied over it, i.e. between the top electrode and the bottom electrode. In FIG. 7, measurement results of this voltage dependency are shown as a change in the measurement curves of the impedance Z and the phase φ. The sensitivity is not very large, but it can be useful to provide a frequency control for an oscillator circuit to be used for reference purposes. As indicated in FIG. 7, a phase change corresponding to approximately 25 kHz/V is obtained at the slope portion near the center frequency of approximately 1.757 GHz. In the measurement curves of the impedance Z, the left minimum value indicates the series resonance, while the right maximum value indicates the parallel resonance.

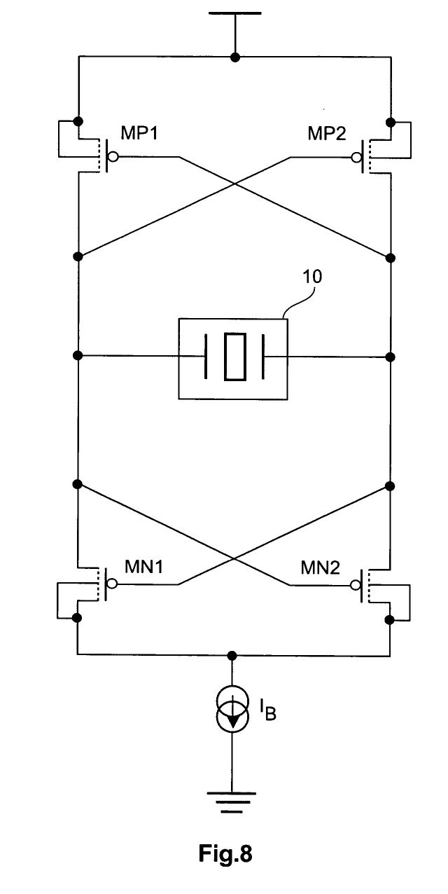

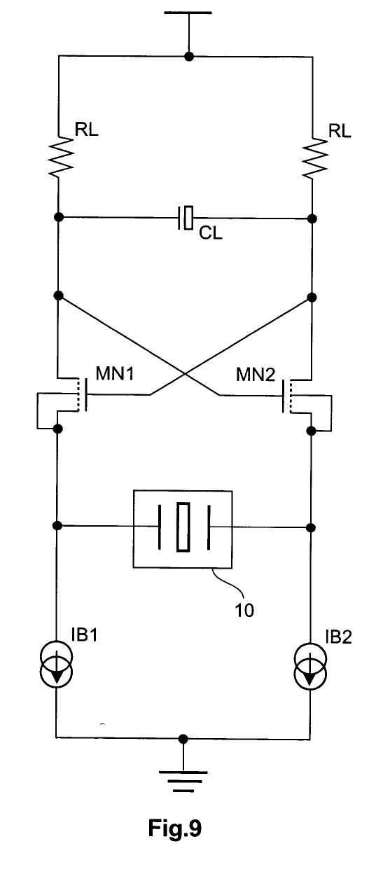

In the following, two examples for use of the proposed FBAR structures according to the first to third preferred embodiments in a differential oscillator circuit are briefly described with reference to FIGS. 8 and 9.

FIG. 8 shows a first example for an implementation of the proposed FBAR structure 10 in a differential oscillator in bridge configuration comprising a first differential transistor pair of P-channel MOSFETs (Metal Oxide Semiconductor Field Effect Transistors) MP1 and MP2 and a second differential transistor pair of N-channel MOSFETs MN1 and MN2. The FBAR structure 10 is connected in a differential topology and diagonally across the bridge configuration at the source terminals of the transistor pairs. This example is suitable for a parallel mode oscillator, where the FBAR structure is operated at its parallel resonance.. A current source is provided to generate a bias current I_{B} for the differential transistor pairs. This differential parallel mode oscillator is advantageous in that a Colpitts type of oscillator can be realized with two-pin resonator connection.

FIG. 9 shows a second example for an implementation of the proposed FBAR structure 10 in a differential oscillator circuit comprising a differential transistor pair of N-channel MOSFETs MN1 and MN2. The FBAR structure 10 is connected in a differential topology between the source terminals of the MOSFETs MN1 and MN2. This example is suitable for a series mode oscillator, where the FBAR is operated at its series resonance. Here, two current sources are provided to generate respective bias currents I_{B1} and I_{B2} for the differential transistors MN1 and MN2, based on load resistors R_{L}. Furthermore, a load capacitor CL is connected across the drain terminals of the transistors MN1 and MN2. This differential series mode oscillator is advantageous in that it is less sensitive to parallel parasitic capacitances and provides better stability due to less sensitivity with respect to pulling and pushing effects.

The above differential oscillator types are more robust to environmental changes. Implementation of such a differential structure in a conventional Butler type oscillator structure would lead to an undesirable increase in circuit complexity and number of connection pins.

The FBAR structures according to the above preferred embodiments can be fabricated on silicon (Si), gallium arsenide (GaAs), glass, or ceramic substrates. One ceramic substrate type, which is widely used, is alumina. The FBAR structures can be manufactured using various thin film manufacturing techniques, such as for example sputtering, vacuum evaporation or chemical vapor deposition.

The resonance frequency may range from 0.5 GHz to several GHz, depending on the size and materials of the FBAR structure. FBARs exhibit the typical series and parallel resonances of crystal resonators. The resonance frequencies are determined mainly by the material of the resonator and the dimensions of the layers of the resonator.

In general, the FBAR structure comprises an acoustically active piezoelectric layer, electrodes on opposite sides of the piezoelectric layer, and acoustical isolation from the substrate. The electrodes not necessarily have to be arranged as top and bottom electrodes but can be oriented in any other direction.

The piezoelectric layer or film 160 may be for example, ZnO, AlN, ZnS or any other piezoelectric material (or combination of them since temperature behavior is possible to control with two different piezoelectric materials) that can be fabricated as a thin film. As a further example, also ferroelectric ceramics can be used as the piezoelectric material. For example, PbTiO₃ and Pb(ZrₓTi₁₋ₖ)O₃ and other members of the so called lead lanthanum zirconate titanate family can be used.

The material used to form the electrode layers can be an electrically conductive material having a high acoustic impedance. The electrodes may be comprised of for example any suitable metal, such as tungsten (W), aluminum (Al), copper (Cu), molybdenum (Mo), nickel (Ni), titanium (Ti), niobium (Nb), silver (Ag), gold (Au), and tantalum (Ta).

The acoustical isolation, as obtained by the acoustic mirror structure of the above embodiments, can be obtained for example by alternative techniques, such as a substrate via-hole or a micromechanical bridge structure. However, the invention is not limited to these three techniques, since any other way of isolating the resonator from the substrate can be used as well.

In the via-hole and bridge structures, the acoustically reflecting surfaces are the air interfaces below and above the FBAR structure. The bridge structure is typically manufactured using a sacrificial layer, which is etched away to produce a free-standing structure. Use of a sacrificial layer makes it possible to use a wide variety of substrate materials, since the substrate does not need to be modified very much, as in the via-hole structure.

The acoustical mirror structure performs the isolation by reflecting the acoustic wave back to the resonator structure. The acoustical mirror 18 of the preferred embodiments typically comprises several layers having a thickness of one quarter wavelength at the center frequency, alternating layers having differing acoustical impedances. The number of layers in an acoustic mirror is an odd integer, typically ranging from three to nine. The ratio of acoustic impedance of two consecutive layers should be large in order to present as low acoustic impedance as possible to the FBAR, instead of the relatively high impedance of the substrate material. The material of the high impedance layers can be for example gold (Au), molybdenum (Mo), or tungsten (W), and the material of the low impedance layers can be for example silicon (Si), polysilicon (poly-Si), silicon dioxide (SiO₂), aluminum (Al), or a polymer. Since in structures utilizing an acoustical mirror structure, the resonator is isolated from the substrate and the substrate is not modified very much, a wide variety of materials can be used as a substrate.

The polymer layer may be comprised of any polymer material having a low loss characteristic and a low acoustic impedance. Preferably, the polymer material is such that it can withstand temperatures of at least 350° C., since relatively high temperatures may be achieved during deposition of other layers of the acoustical mirror structure and other structures. The polymer layer may be comprised of, by example, polyimide, cyclotene, a carbon-based material, a silicon-based material or any other suitable material.

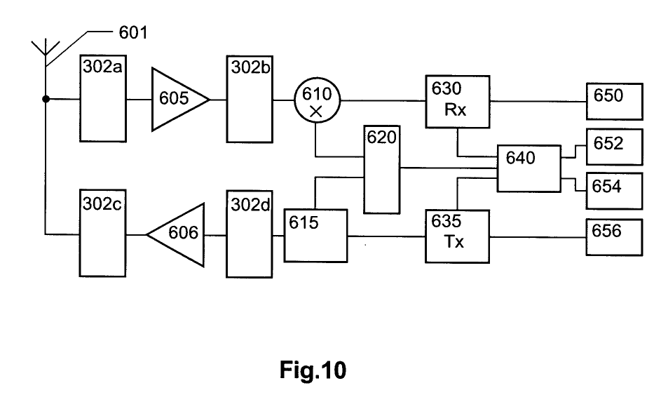

FIG. 10 shows a block diagram of a mobile communication device in which the above embodiments of the invention can be implemented. A receiver part of the mobile communication means comprises a first receiver filter 302a for filtering the received signal, a receiver amplifier 605 for amplifying the received signal, a second receiver filter 302b for further filtering of the received signal, a mixer 610 for converting the received signal to baseband, a receiver block 630 for demodulating and decoding the signal and an earpiece 650 or a loudspeaker 650 for producing the audible received signal. A transmitter part comprises a microphone 656, a transmitter block 635 for coding the signal to be transmitted and performing other necessary signal processing, a modulator 615 for producing the modulated radio frequency signal, a first transmitter filter 302d, a transmitter amplifier 606, and a second transmitter filter 302c.

The mobile communication device further comprises an antenna 601, an oscillator block 620 which may comprise one of the oscillator circuits shown in FIGS. 10 and 1 1 or any other oscillator circuit with a differential FBAR structure according to the above preferred embodiments or any combination thereof, a control block 640, a display 652 and a keypad 654. The control block 640 controls the functioning of the receiver and transmitter blocks and the oscillator block, as well as displays information to the user via the display 652 and receives commands from the user via the keypad 654.

The filters 302a, 302b, 302c, and 302d may comprise, for example, a FBAR structure according to one of the above embodiments or any combination thereof, depending on the width and the number of the operating bands of the mobile communication device. The receiver filters 302a, 302b are used to limit the noise and disturbing signals which the receiver receives from a receiving band. At the transmission side, the transmission filters 302c, 302d can clean up noise generated by the transmission circuitry outside the desired transmission frequencies. The oscillator block 620 may comprise an oscillator with a switched FBAR bank. The oscillator block 620 may further comprise a filter circuits for removing unwanted noise from the output of the oscillator circuit.

In summary, the present invention relates to a resonator structure, such as a bulk acoustic wave (FBAW) resonator structure, which is modified to approximate a parasitic input characteristic to a parasitic output characteristic and thus enable use of the resonator structure in a differential topology. Thereby, crystal-based resonator structures can be replaced by the proposed differential resonator structure, which enables higher integration, reduced costs and higher frequencies.

Furthermore, it is to be noted that the present invention is not restricted to the above preferred embodiment and can be implemented in any resonator structure to obtain a differential topology. The preferred embodiments may thus vary within the scope of the attached claims.

1. A resonator structure integrated on a substrate comprising:
a) an acoustically active layer;
b) a first electrode and a second electrode arranged on opposite sides of said acoustically active layer; and
c) isolation means for acoustically isolating said acoustically active layer from said substrate;
d) wherein said first electrode is extended by a predetermined amount beyond said acoustically active layer, so as to approximate a parasitic input characteristic to a parasitic output characteristic of said resonator structure.

2. A resonator structure according to claim 1, wherein said first electrode is arranged on top of a layered structure comprising said acoustically active layer, said second electrode, said isolation means and said substrate.

3. A resonator structure according to claim 1, wherein said isolation means is extended substantially in parallel to said first electrode and substantially by the same amount.

4. A resonator structure according to claim 1, wherein said first electrode is extended by an amount which substantially corresponds to a length of said second electrode in a direction of extension.

5. A resonator structure according to claim 1, wherein said isolation means comprises a layered acoustic mirror structure.

6. A resonator structure integrated on a substrate, comprising:
a) a first resonator structure having a first acoustically active layer, first opposite electrodes arranged on opposite sides of said first acoustically active layer, and first isolation means for acoustically isolating said first acoustically active layer from said substrate;
b) a second resonator structure having a second acoustically active layer, second opposite electrodes arranged on opposite sides of said second acoustically active layer, and second isolation means for acoustically isolating said second acoustically active layer from said substrate;
c) wherein said first and second opposite electrodes of said first and second resonator structures are connected in an anti-parallel or anti-serial manner, so as to approximate a parasitic input characteristic to a parasitic output characteristic of said resonator structure.

7. A resonator structure according to claim 6, wherein a top electrode of said first opposite electrodes is arranged as a top layer of a layered structure forming said first resonator structure and said substrate, and a top electrode of said second opposite electrodes is arranged as top layer of a layered structure forming said second resonator structure and said substrate, and wherein said anti-parallel structure is obtained by connecting said top electrode of said first opposite electrodes to a bottom electrode of said second opposite electrodes and by connecting said top electrode of said second opposite electrodes to a bottom electrode of said first opposite electrodes.

8. A resonator structure according to claim 6, wherein a top electrode of said first opposite electrodes is arranged as a top layer of a layered structure forming said first resonator structure and said substrate, and a top electrode of said second opposite electrodes is arranged as top layer of a layered structure forming said second resonator structure and said substrate, and wherein said anti-serial structure is obtained by connecting a bottom electrode of said first opposite electrodes to a bottom electrode of said second opposite electrodes.

9. An oscillator circuit comprising a resonator structure according to claim 1, wherein said structure comprises a differential topology.

10. An oscillator circuit according to claim 9, wherein said resonator structure is arranged in a diagonal path of a bridge configuration of differentially operated transistor elements.

11. An oscillator circuit according to claim 9, wherein said resonator structure is connected between source electrodes of differentially operated transistor elements.

12. A radio communication device comprising an oscillator circuit according to claim 9, said oscillator circuit being operated as a local oscillator.

13. A radio communication device according to claim 12, wherein said radio communication device comprises a mobile phone.

14. Use of a bulk acoustic wave resonator according to claim 1 in a differential topology in an oscillator circuit.

15. An apparatus for a resonator structure integrated on a substrate, the apparatus comprising:
a) an acoustically active layer means;
b) a first electrode means and a second electrode means arranged on opposite sides of said acoustically active layer means; and
c) isolation means for acoustically isolating said acoustically active layer means from said substrate;
d) wherein said first electrode means is extended by a predetermined amount beyond said acoustically active layer means, so as to approximate a parasitic input characteristic to a parasitic output characteristic of said resonator structure.
